(19) United States
(12) Patent Application Publication
(10) Pub. No.: US 2026/0302363 A1
(43) Pub. Date: Oct. 1, 2026

(54) METHOD FOR MANUFACTURING SOLID-STATE BATTERY, AND SOLID-STATE BATTERY

(71) Applicant: HONDA MOTOR CO., LTD., Tokyo (JP)

(72) Inventors: Takuya Taniuchi, Wako-shi (JP); Masahiro Hokazono, Wako-shi (JP); Kizashi Iwakiri, Wako-shi (JP); Toshimitsu Tanaka, Wako-shi (JP); Kenta Yoriki, Wako-shi (JP); Hideo Wachi, Wako-shi (JP); Kaoru Takahashi, Wako-shi (JP); Kiyoshi Tanaami, Wako-shi (JP)

(21) Appl. No.: 19/551,687

(22) Filed: Feb. 27, 2026

(30) Foreign Application Priority Data
Mar. 31, 2025 (JP) 2025-059190

(51) Int. Cl. H01M 10/0585; G01R 31/389; H01M 4/02; H01M 4/38; H01M 10/0562

(52) U.S. Cl. CPC H01M 10/0585; G01R 31/389; H01M 4/382; H01M 10/0562; H01M 2004/027

(57) ABSTRACT

The method for manufacturing a solid-state battery is configured to include a first process of forming a plurality of electrode assemblies each including a positive electrode layer, a solid electrolyte layer, and a negative electrode layer, a second process of selecting a plurality of set resistance electrode assemblies from the plurality of electrode assemblies so that a coefficient of variation in resistance values of the plurality of electrode assemblies falls within a predetermined range, a third process of stacking the set resistance electrode assemblies to form an electrode assembly stack, and a fourth process of chemically forming the electrode assembly stack.

### CROSS-REFERENCE TO RELATED APPLICATION

Priority is claimed on Japanese Patent Application No. 2025-059190, filed Mar. 31, 2025, the content of which is incorporated herein by reference.

### BACKGROUND OF THE INVENTION

### Field of the Invention

The present invention relates to a method for manufacturing a solid-state battery, and a solid-state battery.

### Description of Related Art

In recent years, in order to ensure that more people have access to affordable, reliable, sustainable, and advanced energy, research and development has been conducted on solid-state batteries, which contribute to energy efficiency.

There is a demand for further improvements in the energy density of solid-state batteries. As a method for improving the energy density of solid-state batteries, the use of an electrode assembly stack formed by stacking a plurality of electrode assemblies including a positive electrode layer, a solid electrolyte layer, and a negative electrode layer, has been researched.

Patent Document 1 describes a cell structure including a sheet-shaped cathode, a sheet-shaped anode, and a sheet-shaped solid electrolyte layer interposed between the cathode and the anode. Also, Patent Document 1 describes that the solid electrolyte layer of the cell structure is stacked on the anode, and the cathode is stacked on the solid electrolyte layer. In addition, Patent Document 1 describes a cell structure with low resistance in which a resistance Rc of the cathode and a resistance Ra of the anode and solid electrolyte layer satisfy a relationship of Rc/Ra≥0.3, the cathode includes a first metal oxide having a perovskite-type crystal structure, and a thickness of the cathode is greater than 15 μm and less than or equal to 30 μm.

Patent Document 2 describes a solid-state battery including a positive electrode layer, a negative electrode layer, and a solid electrolyte layer disposed between the positive electrode layer and the negative electrode layer, and a method for manufacturing the solid-state battery. The solid-state battery described in Patent Document 2 is described such that the negative electrode layer includes an aluminum layer in contact with the solid electrolyte layer, a lithium layer, and an aluminum-lithium alloy layer disposed between the aluminum layer and the lithium layer. Patent Document 2 describes that, by including the aluminum layer in contact with the solid electrolyte layer and the lithium layer in contact with the aluminum layer, it is possible to provide a solid-state battery that is resistant to a decrease in discharge capacity and an increase in DCR resistance even with repeated charge and discharge.

Patent Document 3 describes a battery stack that can inhibit an increase in internal resistance. Specifically, the battery stack is described to have a power generating element formed by stacking one or a plurality of electrode assemblies, each of which has a positive electrode layer, a solid electrolyte layer, and a negative electrode layer stacked in order, a positive electrode terminal electrically connected to the positive electrode layer, a negative electrode terminal electrically connected to the negative electrode layer, a positive electrode metal sputtered layer disposed between the power generating element and the positive electrode terminal, a negative electrode metal sputtered layer disposed between the power generating element and the negative electrode terminal; and an exterior body. In the battery stack described in Patent Document 3, the positive electrode terminal and the negative electrode terminal are sintered or fusion-bonded metal bodies, the power generating element contains sulfur, a material of the positive electrode metal sputtered layer and/or the negative electrode metal sputtered layer is at least one selected from the group including gold, platinum, nickel, and stainless steel, and the power generating element is sealed by the exterior body, the negative electrode terminal, and the positive electrode terminal.

### PATENT DOCUMENTS

[Patent Document 1] PCT International Publication No. WO 2019/171905
[Patent Document 2] PCT International Publication No. WO 2019/151376
[Patent Document 3] Japanese Patent No. 7622706

### SUMMARY OF THE INVENTION

Incidentally, in the field of solid-state battery technology, in the case of manufacturing solid-state batteries including an electrode assembly stack in which a plurality of electrode assemblies are stacked, it is difficult to obtain solid-state batteries with the required performance, and improving manufacturing yields remains a challenge.

The present application has been made in view of the above-mentioned problems, and an object thereof is to provide a method for manufacturing a solid-state battery with which a solid-state battery including an electrode assembly stack formed by stacking a plurality of electrode assemblies can be manufactured with a high yield. In addition, the present application also contributes to improving energy efficiency. Further, another object of the present application is to provide a solid-state battery that can be manufactured with a high yield using the method for manufacturing a solid-state battery of the present application.

In order to solve the above problems, the following means are provided.

A method for manufacturing a solid-state battery of a first aspect of the present invention includes a first process of forming a plurality of electrode assemblies (1) each including a positive electrode layer (11), a solid electrolyte layer (13), and a negative electrode layer (12), a second process of selecting a plurality of set resistance electrode assemblies (1a) from the plurality of electrode assemblies (1) so that a coefficient of variation in resistance values of the plurality of electrode assemblies (1) falls within a predetermined range, a third process of stacking the set resistance electrode assemblies (1a) to form an electrode assembly stack (10), and a fourth process of chemically forming the electrode assembly stack (10).

In the method for manufacturing a solid-state battery of the first aspect, the plurality of electrode assemblies (1) are formed, and the plurality of set resistance electrode assemblies (1a) are selected from the plurality of electrode assemblies (1) so that the coefficient of variation in the resistance values of the plurality of electrode assemblies (1) falls within the predetermined range. Then, the set resistance electrode assemblies (1a) are stacked to form the electrode assembly stack (10), and the electrode assembly stack (10) is chemically formed. Accordingly, according to the method for manufacturing a solid-state battery of the first aspect, variation in the resistance values of the set resistance electrode assemblies (1a) included in the electrode assembly stack (10) is sufficiently small. For this reason, the solid-state battery with a sufficient capacity is likely to be obtained, and the solid-state battery including the electrode assembly stack (10) formed by stacking the plurality of electrode assemblies (1) can be manufactured with a high yield.

A method for manufacturing a solid-state battery of a second aspect of the present invention is configured such that the resistance values according to the manufacturing method of the first aspect are AC resistance values.

In the method for manufacturing a solid-state battery of the second aspect, since a coefficient of variation in the AC resistance values is used as the coefficient of variation in the resistance values of the plurality of electrode assemblies (1), the resistance values of each of the electrode assemblies (1) can be measured in a shorter time as compared to a case in which DC resistance values are used. For this reason, the coefficient of variation in the resistance values of each of the electrode assemblies (1) can be calculated in a shorter time, and the variation in the resistance values of each of the set resistance electrode assemblies (1a) forming the electrode assembly stack (10) can be efficiently inhibited.

A method for manufacturing a solid-state battery of a third aspect of the present invention is configured such that, in the second process according to the manufacturing method of the first aspect, the plurality of set resistance electrode assemblies (1a) are selected from the plurality of electrode assemblies (1) so that the AC resistance values of the plurality of electrode assemblies (1) fall within the predetermined range calculated on the basis of a set DC resistance value of the electrode assembly stack (10) when discharged for 10 seconds after the chemical formation is performed in the fourth process.

In the method for manufacturing a solid-state battery of the third aspect, the plurality of set resistance electrode assemblies (1a) are selected from the plurality of electrode assemblies (1) so that the AC resistance values of the plurality of electrode assemblies (1) falls within the predetermined range calculated on the basis of the set DC resistance value of the electrode assembly stack (10). For this reason, the electrode assembly stack (10) whose DC resistance value (DCR) when discharged for 10 seconds after the chemical formation falls within the range of the set DC resistance value is more likely to be formed, and the yield of electrode assembly stack (10) at the time of completion of the chemical formation is improved.

A method for manufacturing a solid-state battery of a fourth aspect of the present invention is configured such that, in the second process according to the manufacturing method of the first aspect, the plurality of set resistance electrode assemblies (1a) are selected from the plurality of electrode assemblies (1) so that the set DC resistance value when the electrode assembly stack (10) is chemically formed and discharged for 10 seconds can be approximated by a function of the AC resistance values of the electrode assemblies (1).

In the method for manufacturing a solid-state battery of the fourth aspect, in the second process, the plurality of set resistance electrode assemblies (1a) are selected from the plurality of electrode assemblies (1) so that the set DC resistance value when the electrode assembly stack (10) is chemically formed and discharged for 10 seconds can be approximated by the function of the AC resistance values of the electrode assemblies (1). For this reason, the electrode assembly stack (10) whose DC resistance value (DCR) when discharged for 10 seconds after the chemical formation falls within the range of the set DC resistance value is more likely to be formed. Accordingly, the yield of the electrode assembly stack (10) at the time of completion of the chemical formation is further improved.

A method for manufacturing a solid-state battery of a fifth aspect of the present invention is configured such that, in the second process according to the manufacturing method of the first aspect, the plurality of set resistance electrode assemblies (1a) are selected from the plurality of electrode assemblies (1) so that a relationship between the set DC resistance value when the electrode assembly stack (10) is chemically formed and discharged for 10 seconds and the AC resistance values of the electrode assemblies (1) can be linearly approximated.

In the method for manufacturing a solid-state battery of the fifth aspect, in the second process, the plurality of set resistance electrode assemblies (1a) are selected from the plurality of electrode assemblies (1) so that the relationship between the set DC resistance value when the electrode assembly stack (10) is chemically formed and discharged for 10 seconds and the AC resistance values of the electrode assemblies (1) can be linearly approximated. For this reason, the electrode assembly stack (10) whose DC resistance value (DCR) when discharged for 10 seconds after the chemical formation falls within the range of the set DC resistance value is more likely to be formed.

A method for manufacturing a solid-state battery of a sixth aspect of the present invention is configured such that the resistance values according to the manufacturing method of the first aspect are AC resistance values, and the coefficient of variation of the resistance values is 15% or less.

A method for manufacturing a solid-state battery of a seventh aspect of the present invention is configured such that the resistance values according to the manufacturing of the first aspect are AC resistance values, and the coefficient of variation of the resistance values is 10% or less.

In the method for manufacturing a solid-state battery of the sixth aspect and the method for manufacturing a solid-state battery of the seventh aspect, since the resistance values are AC resistance values, and the coefficient of variation of the resistance values is 15% or less or 10% or less, variation in the resistance values for each of the set resistance electrode assemblies (1a) forming the electrode assembly stack (10) is more effectively inhibited, making it easier to obtain the solid-state battery with a large capacity.

A method for manufacturing a solid-state battery of an eighth aspect of the present invention is configured such that, by chemically forming the electrode assembly stack (10) in the fourth process according to the manufacturing method of the first aspect, the electrode assembly stack (10) in which the coefficient of variation of the DC resistance values of the plurality of set resistance electrode assemblies (1a) forming the electrode assembly stack (10) is 10% or less is manufactured.

In the method for manufacturing a solid-state battery of the eighth aspect, the solid-state battery with excellent characteristics in which the coefficient of variation of the DC resistance values of the plurality of set resistance electrode assemblies (1a) forming the electrode assembly stack (10) is 10% or less is obtained.

A method for manufacturing a solid-state battery of a ninth aspect of the present invention is configured such that, by chemically forming the electrode assembly stack (10) in the fourth process according to the manufacturing method of the first aspect, the electrode assembly stack (10) having a DC resistance value of 20 Ωcm² or less at a temperature of 60° C. is manufactured.

In the method for manufacturing a solid-state battery of the ninth aspect of the present invention, the solid-state battery with excellent characteristics including the electrode assembly stack (10) having a DC resistance value of 20 Ωcm² or less at a temperature of 60° C. is obtained.

A method for manufacturing a solid-state battery of a tenth aspect of the present invention is configured such that the plurality of set resistance electrode assemblies (1a) are selected from the plurality of electrode assemblies (1) in the second process according to the manufacturing method of the first aspect so that a coefficient of variation in capacities of the plurality of set resistance electrode assemblies (1a) falls within a predetermined range. In the method for manufacturing a solid-state battery of the tenth aspect, since the plurality of set resistance electrode assemblies (1a) are selected from the plurality of electrode assemblies (1) in the second process so that the coefficient of variation in capacity of the plurality of set resistance electrode assemblies (1a) falls within a predetermined range, the electrode assembly stack (10) in which the variation in the capacities of the plurality of set resistance electrode assemblies (1a) are reduced is obtained.

A method for manufacturing a solid-state battery of an eleventh aspect of the present invention is configured such that the coefficient of variation in the capacities according to the manufacturing method of the tenth aspect is 5% or less.

A method for manufacturing a solid-state battery of a twelfth aspect of the present invention is configured such that the coefficient of variation in the capacities according to the manufacturing method of the tenth aspect is 3% or less.

In the method for manufacturing a solid-state battery of the eleventh aspect and the method for manufacturing a solid-state battery of the twelfth aspect, the plurality of set resistance electrode assemblies (1a) are selected from the plurality of electrode assemblies (1) so that the coefficient of variation in the capacities is 5% or less or 3% or less, the electrode assembly stack (10) with less variation in the capacities of the plurality of set resistance electrode assemblies (1a) is obtained.

A method for manufacturing a solid-state battery of a thirteenth aspect of the present invention is configured such that the negative electrode layer (12) according to the manufacturing method of the first aspect contains lithium metal or a lithium alloy.

In the method for manufacturing a solid-state battery of the thirteenth aspect, the solid-state battery is obtained in which the variation in the resistance values of the set resistance electrode assemblies (1a) included in the electrode assembly stack (10) is sufficiently small, uniformity of battery reactions in each of the set resistance electrode assemblies (1a) is likely to be ensured, and the negative electrode layer (12) contains lithium metal or a lithium alloy. For this reason, the energy density improvement effect obtained by the negative electrode layer (12) including lithium metal or a lithium alloy is more effectively achieved, and a solid-state battery with a higher energy density is obtained.

A solid-state battery of a fourteenth aspect of the present invention is manufactured by the method for manufacturing a solid-state battery described in the first aspect.

Since the solid-state battery of the fourteenth aspect is manufactured by the method for manufacturing a solid-state battery described in the first aspect, it includes the electrode assembly stack (10) in which the plurality of set resistance electrode assemblies (1a) are stacked, and can be manufactured with a high yield.

A solid-state battery of a fifteenth aspect of the present invention includes an electrode assembly stack (10) in which a plurality of electrode assemblies (1) are stacked, each of which includes a positive electrode layer (11), a solid electrolyte layer (13), and a negative electrode layer (12).

The electrode assembly stack (10) has a specific capacity per positive electrode active material of 150 mAh/g or more, and the electrode assembly stack (10) has a DC resistance value of 18 Ωcm² or less at 60° C. when discharged for 10 seconds.

The solid-state battery of the fifteenth aspect has excellent characteristics because it includes the electrode assembly stack (10) in which the plurality of electrode assemblies (1) are stacked, the electrode assembly stack (10) has a specific capacity per positive electrode active material of 150 mAh/g or more, and the electrode assembly stack (10) has a DC resistance value of 18 Ωcm² or less at 60° C. when discharged for 10 seconds.

A solid-state battery of a sixteenth aspect of the present invention is configured such that, in the solid-state battery of the fifteenth aspect, the specific capacity per positive electrode active material of the electrode assembly stack (10) is 150 mAh/g or more, and the DC resistance value at 60° C. when the electrode assembly stack (10) is discharged for 10 seconds is 2 Ωcm² or more and 17 Ωcm² or less.

The solid-state battery of the sixteenth aspect has more excellent characteristics because the specific capacity per positive electrode active material of the electrode assembly stack (10) is 150 mAh/g or more, and the DC resistance value at 60° C. when the electrode assembly stack (10) is discharged for 10 seconds is 2 Ωcm² or more and 17 Ωcm² or less.

In the method for manufacturing a solid-state battery of the present invention, the plurality of electrode assemblies are formed, and the plurality of set resistance electrode assemblies are selected from the plurality of electrode assemblies so that the coefficient of variation in the resistance values of the plurality of electrode assemblies falls within the predetermined range. Then, the set resistance electrode assemblies are stacked to form the electrode assembly stack, and the electrode assembly stack is chemically formed. Accordingly, according to the method for manufacturing a solid-state battery of the present invention, the variation in the resistance values of the set resistance electrode assemblies included in the electrode assembly stack is sufficiently small. For this reason, the solid-state battery including the electrode assembly stack formed by stacking the plurality of electrode assemblies can be manufactured with a high yield.

### BRIEF DESCRIPTION OF THE DRAWINGS

FIG. 1 is a schematic cross-sectional view for illustrating an example of an electrode assembly stack included in a solid-state battery according to the present embodiment.

FIG. 2 is a schematic cross-sectional view for illustrating another example of an electrode assembly included in a solid-state battery according to the present embodiment.

### DETAILED DESCRIPTION OF THE INVENTION

In order to solve the above problems and manufacture a solid-state battery including an electrode assembly stack formed by stacking a plurality of electrode assemblies with a high yield, the present inventors have conducted extensive research, focusing on a process of stacking the plurality of electrode assemblies to form the electrode assembly stack in manufacturing processes for the solid-state battery.

As a result, the present inventors have found that, when the number of stacked electrode assemblies forming the electrode assembly stack, in which the plurality of electrode assemblies are connected in parallel to each other, is increased in order to improve the energy density of the solid-state battery, it becomes difficult to obtain a solid-state battery with specified performance, resulting in a lower manufacturing yield. For this reason, the present inventors have conducted further research, focusing on the process of stacking the plurality of electrode assemblies to form the electrode assembly stack.

As a result, it has been found that, in a solid-state battery including an electrode assembly stack formed by stacking many electrode assemblies connected in parallel to each other, there is large variation in resistance values of each of the electrode assemblies, and thus it becomes difficult to obtain a solid-state battery with specified performance, resulting in a low manufacturing yield. This is because, in the electrode assembly stack formed by stacking many electrode assemblies connected in parallel to each other, if even one of the plurality of electrode assemblies has a resistance value higher than a predetermined value, abnormalities due to charging and discharging will occur inside the electrode assembly stack.

Thus, the present inventors have conducted extensive research to improve the uniformity of the resistance values of each of the electrode assemblies forming the electrode assembly stack. As a result, it has been found that a plurality of set resistance electrode assemblies can be selected from a plurality of electrode assemblies so that a coefficient of variation in the resistance values of the plurality of electrode assemblies falls within a predetermined range, and these can be stacked to form the electrode assembly stack in which the plurality of set resistance electrode assemblies are connected in parallel to each other.

Since the electrode assembly stack obtained in this manner has small variation in the resistance values of each of the electrode assemblies included in the electrode assembly stack, a solid-state battery with a sufficient capacity is likely to be obtained.

Further, the present inventors have confirmed that, by forming the plurality of electrode assemblies, selecting the plurality of set resistance electrode assemblies from the plurality of electrode assemblies so that the coefficient of variation of the resistance values of the plurality of electrode assemblies falls within the predetermined range, and stacking these to form the electrode assembly stack in which the plurality of set resistance electrode assemblies are connected in parallel to each other, the solid-state battery including the electrode assembly stack formed by stacking the plurality of electrode assemblies connected in parallel to each other can be manufactured with a high yield, and have conceived the present invention.

A method for manufacturing a solid-state battery and a solid-state battery of the present embodiment will be described in detail below, with appropriate reference to the drawings. The drawings used in the following description may conveniently show characteristic portions enlarged to make the features of the present invention easier to understand. Accordingly, dimensional ratios of each constituent element or the like may differ from actual ones. Materials, dimensions, and the like exemplified in the following description are merely examples, and the present invention is not limited thereto and can be modified and implemented as appropriate within the range of not changing the gist thereof.

### [Solid-State Battery]

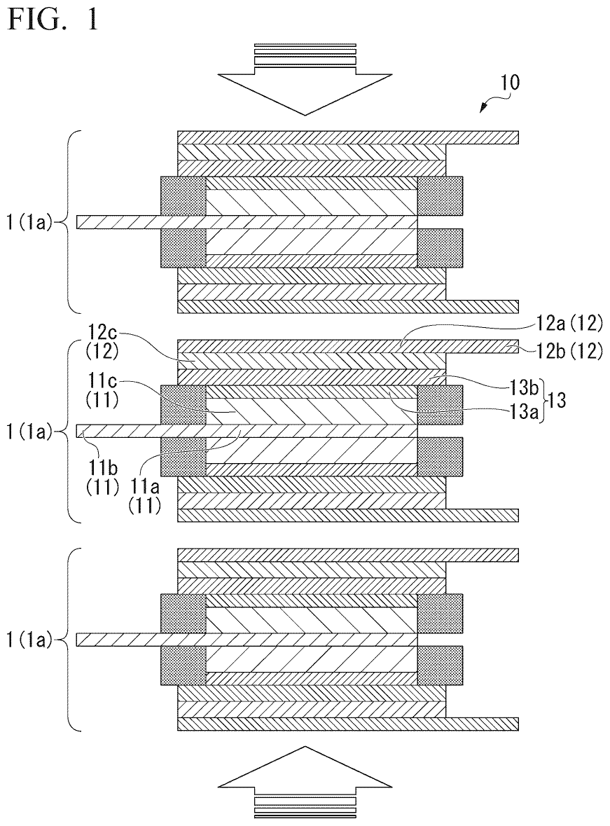

FIG. 1 is a schematic cross-sectional view for illustrating an example of an electrode assembly stack included in a solid-state battery according to the present embodiment.

The solid-state battery of the present embodiment includes an electrode assembly stack 10 shown in FIG. 1, a restraining jig (not shown) that restrains the electrode assembly stack 10, and a case (exterior body) (not shown) that houses the electrode assembly stack 10.

The electrode assembly stack 10 included in the solid-state battery of the present embodiment is manufactured by the method for manufacturing a solid-state battery of the present embodiment, which will be described later. A known device such as an end plate can be used as the restraining jig. Also, a known device that can be used as a case for a solid-state battery can be used as the case.

### (Electrode Assembly Stack 10)

As shown in FIG. 1, the electrode assembly stack 10 is formed by stacking a plurality (three layers in FIG. 1) of electrode assemblies 1 (set resistance electrode assemblies 1a). In the present embodiment, the plurality of electrode assemblies 1 forming the electrode assembly stack 10 are connected in parallel to each other. For this reason, it becomes easier to predict a resistance value of the entire electrode assembly stack 10 from a single electrode assembly 1, making it possible to manufacture a high-capacity solid-state battery with a high yield as compared to, for example, a case in which the plurality of electrode assemblies 1 forming the electrode assembly stack 10 are connected in series to each other.

The number of stacked electrode assemblies 1 included in the electrode assembly stack 10 may be, for example, 5, 7, 12, 27, or the like, and can be determined appropriately depending on the application of the solid-state battery and is not particularly limited. It is preferable that the number of layers of the electrode assemblies 1 be larger because the effects of manufacturing the solid-state battery using the method for manufacturing a solid-state battery of the present embodiment described below are more pronounced, and specifically, when the number of layers in the electrode assemblies 1 is 10 or more, the effects of using the manufacturing method of the present embodiment become more pronounced.

Each of the electrode assemblies 1 (set resistance electrode assemblies 1a) forming the electrode assembly stack 10 includes a positive electrode layer 11, a solid electrolyte layer 13, a negative electrode layer 12, and an insulating member 14. In the present embodiment, as an example of a preferred electrode assembly 1, as shown in FIG. 1, a case in which two positive electrode layers 11 disposed inside a frame-shaped insulating member 14 are disposed to face each other, and a solid electrolyte layer 13 and a negative electrode layer 12 are disposed in order respectively on both sides in a thickness direction thereof will be described as an example.

A positive electrode active material layer 11c included in the positive electrode layer 11, a negative electrode active material layer 12c included in the negative electrode layer 12, the solid electrolyte layer 13, and the insulating member 14, which form the electrode assembly 1 shown in FIG. 1, all have generally rectangular outer shapes in a plan view. In the electrode assembly 1, in a plan view, outer surfaces of the positive electrode active material layer 11c, the negative electrode active material layer 12c, and a negative electrode side solid electrolyte layer 13b of the solid electrolyte layer 13 are disposed inward from an outer surface of the insulating member 14, and the positive electrode active material layer 11c and a positive electrode side solid electrolyte layer 13a of the solid electrolyte layer 13 are disposed inward from the outer surfaces of the negative electrode active material layer 12c and the negative electrode side solid electrolyte layer 13b.

Further, in the electrode assembly 1 shown in FIG. 1, a positive electrode current collector tab 11b included in the positive electrode layer 11 and a negative electrode current collector tab 12b included in the negative electrode layer 12 are disposed to extend in opposite directions (left and right directions in FIG. 1) relative to the electrode assembly stack 10.

### [Positive Electrode Layer 11]

The positive electrode layer 11 can be a known positive electrode layer 11 used as a positive electrode in a solid-state battery. The positive electrode layer 11 has, for example, a sheet-shaped positive electrode current collector 11a and a sheet-shaped positive electrode active material layer 11c.

In the electrode assembly stack 10 shown in FIG. 1, one layer of positive electrode current collector 11a is disposed between positive electrode active material layers 11c of two positive electrode layers 11. In other words, the positive electrode active material layers 11c are disposed in contact with both sides of the one layer of positive electrode current collector 11a. Thus, in the electrode assembly stack 10 shown in FIG. 1, the one layer of positive electrode current collector 11a is configured to serve as the positive electrode current collector 11a for the two adjacent positive electrode layers 11.

The positive electrode current collector 11a is not particularly limited, and metal foil such as stainless steel (SUS) foil or aluminum (Al) foil can be used therefor. The positive electrode current collector 11a of the positive electrode layer 11 is electrically connected to the positive electrode current collector tab 11b that extends outward from the positive electrode current collector 11a and is molded integrally with the positive electrode current collector 11a.

The positive electrode current collector tab 11b does not have to be molded integrally with the positive electrode current collector 11a, and may be formed from a member different from the positive electrode current collector 11a. If the positive electrode current collector tab 11b is formed from a member different from the positive electrode current collector 11a, the positive electrode current collector tab 11b is electrically connected to the positive electrode current collector 11a by a known method such as welding or fusion bonding.

The positive electrode active material layer 11c can be made of a material containing a positive electrode active material known as a positive electrode active material for a solid-state battery. The positive electrode active material layer 11c may contain a solid electrolyte, a conductive additive, a binder, and the like in addition to the positive electrode active material.

If the solid-state battery is a lithium-ion solid-state battery, the positive electrode active material layer 11c can be made of a material containing, for example, a transition metal chalcogenide such as titanium disulfide, molybdenum disulfide, or niobium selenide, a transition metal oxide such as lithium nickel oxide (LiNiO₂), lithium manganese oxide (LiMnO₂, LiMn₂O₄), or lithium cobalt oxide (LiCoO₂), or the like.

The content of the positive electrode active material contained in the positive electrode active material layer 11c is preferably in the range of 60% to 95% by mass, and more preferably in the range of 70% to 85% by mass. If the content of the positive electrode active material is within the above range, in-plane resistance distribution can be curbed even when the electrode assembly stack 10 is increased in output and/or area.

The total basis weight of the two positive electrode active material layers 11c contained in each of the electrode assemblies 1 is preferably in the range of 10 mg/cm² to 80 mg/cm², and more preferably in the range of 28 mg/cm² to 65 mg/cm². If the total basis weight of the two positive electrode active material layers 11c contained in the electrode assembly 1 is 10 mg/cm² or more, the electrode assembly 1 will have a high output. If the basis weight of the positive electrode active material layer 11c is 80 mg/cm² or less, the electrode assembly 1 will have a high capacity and can ensure the required output.

### [Negative Electrode Layer 12]

The negative electrode layer 12 can be a known negative electrode layer 12 used as the negative electrode of a solid-state battery. The negative electrode layer 12 has, for example, a sheet-shaped negative electrode current collector 12a and a sheet-shaped negative electrode active material layer 12c.

The negative electrode current collector 12a is not particularly limited, and metal foil such as stainless steel (SUS) foil or copper (Cu) foil can be used therefor. The negative electrode current collector 12a of the negative electrode layer 12 is electrically connected to the negative electrode current collector tab 12b that extends outward from the negative electrode current collector 12a and is molded integrally with the negative electrode current collector 12a.

The negative electrode current collector tab 12b does not have to be molded integrally with the negative electrode current collector 12a, and may be formed from a member different from the negative electrode current collector 12a. When the negative electrode current collector tab 12b is formed from a member different from the negative electrode current collector 12a, the negative electrode current collector tab 12b is electrically connected to the negative electrode current collector 12a by a known method such as welding or fusion bonding.

The negative electrode active material layer 12c can be made of a material containing a negative electrode active material known as a negative electrode active material for a solid-state battery.

When the solid-state battery is a lithium-ion solid-state battery, the negative electrode active material layer 12c can be made of a material containing, for example, lithium metal, a lithium alloy, a metal oxide, a metal sulfide, a metal nitride, Si, SiO, or a carbon material such as graphite, hard carbon, or soft carbon. The negative electrode active material layer 12c preferably contains lithium metal or a lithium alloy because a solid-state battery with a high energy density can be obtained.

More specifically, for example, if the negative electrode active material of the negative electrode active material layer 12c is made of a carbon material, lithium ions enter and exit the negative electrode active material layer. In contrast, in the negative electrode active material layer 12c containing lithium metal or a lithium alloy, lithium precipitates in a laminating direction of the lithium metal or lithium alloy. For this reason, in a case in which the negative electrode active material layer 12c contains lithium metal or a lithium alloy, if variations in resistance values of the set resistance electrode assemblies 1a are sufficiently small and battery reactions in each of the set resistance electrode assemblies 1a are uniform, lithium is more likely to precipitate more uniformly in an in-plane direction of the negative electrode layer 12 included in each of the set resistance electrode assemblies 1a. As a result, the energy density improvement effect due to the solid-state battery in which the negative electrode active material layer 12c contains lithium metal or a lithium alloy can be more effectively obtained. When the negative electrode active material layer 12c is made of lithium metal foil, a thickness of the lithium metal foil is preferably in the range of 1 μm to 30 μm, and more preferably in the range of 3 μm to 10 μm. When the thickness of the lithium metal foil is within the above range, the electrode assembly 1 has a high energy density and inhibits deterioration in cycle performance.

### [Solid Electrolyte Layer 13]

As shown in FIG. 1, the solid electrolyte layer 13 is laminated between the positive electrode layer 11 and the negative electrode layer 12. The solid electrolyte layer 13 in the electrode assembly 1 shown in FIG. 1 has a laminated structure formed by laminating two layers including the positive electrode side solid electrolyte layer 13a disposed on the positive electrode layer 11 side, and the negative electrode side solid electrolyte layer 13b disposed on the negative electrode layer 12 side. The positive electrode side solid electrolyte layer 13a and the negative electrode side solid electrolyte layer 13b may be the same or different from each other. If the positive electrode side solid electrolyte layer 13a and the negative electrode side solid electrolyte layer 13b are different from each other, they may differ in one or more aspects selected from thickness, planar shape, and material, for example.

The positive electrode side solid electrolyte layer 13a and the negative electrode side solid electrolyte layer 13b contain a solid electrolyte material. The positive electrode side solid electrolyte layer 13a and the negative electrode side solid electrolyte layer 13b transfer ions between the positive electrode active material included in the positive electrode active material layer 11c and the negative electrode active material included in the negative electrode active material layer 12c via the solid electrolyte material.

The solid electrolyte material contained in the positive electrode side solid electrolyte layer 13a and the negative electrode side solid electrolyte layer 13b is not particularly limited, and a known solid electrolyte material can be used therefor. Specifically, as the solid electrolyte material, a sulfide solid electrolyte material, an oxide solid electrolyte material, a nitride solid electrolyte material, a halide solid electrolyte material, or the like can be used, and it is preferable to use a sulfide solid electrolyte material.

The content of the solid electrolyte material contained in the positive electrode side solid electrolyte layer 13a is preferably in the range of 95% to 99% by mass. When the content of the solid electrolyte material is within the above range, the formation of voids in the positive electrode side solid electrolyte layer 13a can be inhibited, the resistance of the positive electrode side solid electrolyte layer 13a can be reduced, and lithium electrodeposition in the positive electrode side solid electrolyte layer 13a can be inhibited.

A thickness of the positive electrode side solid electrolyte layer 13a is preferably in the range of 0.5 μm to 15 μm, and more preferably in the range of 1 μm to 5 μm. If the thickness of the positive electrode side solid electrolyte layer 13a is within the above range, an interface between the positive electrode layer 11 and the positive electrode active material layer 11c is favorably formed, and interfacial resistance with the positive electrode active material layer 11c can be inhibited.

The content of the solid electrolyte material contained in the negative electrode side solid electrolyte layer 13b is preferably in the range of 90% to 99% by mass. If the content of the solid electrolyte material is within the above range, the formation of voids in the negative electrode side solid electrolyte layer 13b can be inhibited, and a decrease in the ionic conductivity of the negative electrode side solid electrolyte layer 13b can be inhibited.

A thickness of the negative electrode side solid electrolyte layer 13b is preferably in the range of 15 μm to 120 μm, and more preferably in the range of 20 μm to 60 μm. If the thickness of the negative electrode side solid electrolyte layer 13b is within the above range, the mechanical strength of the negative electrode side solid electrolyte layer 13b is sufficiently high, resulting in an electrode assembly stack 10 with good durability.

### [Insulating Member 14]

As shown in FIG. 1, each of the electrode assemblies 1 forming the electrode assembly stack 10 has a frame-shaped insulating member 14 that horizontally covers a periphery of the positive electrode active material layer 11c of the positive electrode layer 11 and a periphery of the positive electrode side solid electrolyte layer 13a. The insulating member 14 and the positive electrode active material layer 11c may be integrated or separate members.

In the electrode assembly stack 10 of the solid-state battery of the present embodiment, since the entire periphery of side surfaces of the positive electrode active material layer 11c of the generally rectangular positive electrode layer 11 in a plan view is covered by the insulating member 14, resulting in a highly safe solid-state battery that can ensure insulation between the positive electrode layer 11 and the negative electrode layer 12. Further, the insulating member 14 is disposed to surround the outer periphery of the positive electrode active material layer 11c of the positive electrode layer 11, and thus even if the set resistance electrode assemblies 1a are misaligned in the horizontal direction, uniformity in pressure applied to each of the set resistance electrode assemblies 1a is likely to be ensured due to a thickness of the insulating member 14. As a result, a solid-state battery with predetermined performance is more easily obtained.

A material for forming the insulating member 14 is not particularly limited as long as it has insulating properties. Specifically, for example, resins such as Nomex (registered trademark), polyethylene terephthalate, polystyrene, polyvinyl chloride, polycarbonate, polyethylene, polypropylene, or polyimide, fluorine-based resins such as polyvinylidene fluoride or polytetrafluoroethylene, ceramics such as alumina, insulating materials made by mixing these, or the like can be used.

In the solid-state battery of the present embodiment, a specific capacity of the electrode assembly stack 10 is 150 mAh/g or more. An upper limit of the specific capacity of the electrode assembly stack 10 is not particularly limited, but may be, for example, 250 mAh/g or less, or 220 mAh/g or less.

In the solid-state battery of the present embodiment, since variations in the resistance values of each of the electrode assemblies 1 forming the electrode assembly stack 10 are inhibited, the specific capacity of the electrode assembly stack 10 is equivalent to a specific capacity of an electrode assembly 1 (single cell) before it is stacked.

In the solid-state battery of the present embodiment, a DC resistance value of the electrode assembly stack 10 at a temperature of 60° C. when discharged for 10 seconds is 18 Ωcm² or less. The DC resistance value of the electrode assembly stack 10 at a temperature of 60° C. when discharged for 10 seconds may be 2 Ωcm² or more and 17 Ωcm² or less.

In the present embodiment, the solid-state battery having the electrode assembly 1 shown in FIG. 1 has been described as an example, but it is sufficient if the electrode assembly 1 includes the positive electrode layer 11, the solid electrolyte layer 13, and the negative electrode layer 12, and it may not include the insulating member 14, or may include only one of two insulating members 14 of the electrode assembly 1.

In addition, in the present embodiment, the case in which the insulating member 14 covers the entire periphery of the side surfaces of the positive electrode active material layer 11c of the positive electrode layer 11 and the positive electrode side solid electrolyte layer 13a in a plan view has been described as an example, but the insulating member 14 may be disposed only on a part of the outer periphery of the positive electrode layer 11.

Also, shapes and a stacking order of the positive electrode layer 11, the solid electrolyte layer 13, and the negative electrode layer 12 forming the electrode assembly 1 are not limited to those of the example of the electrode assembly 1 shown in FIG. 1. For example, two negative electrode layers may be disposed to face a negative electrode current collector, with a solid electrolyte layer and a positive electrode layer disposed in order respectively on both sides thereof in the thickness direction.

Further, in the above-described embodiment, the case in which, as the electrode assembly 1, one layer of positive electrode current collector 11a serves as the positive electrode current collector 11a for two adjacent positive electrode layers 11 has been described as an example, but two positive electrode layers 11 may each have a positive electrode current collector 11a.

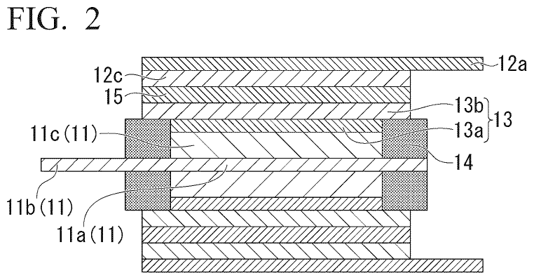

In addition, in the present embodiment, as shown in FIG. 2, it is also preferable to use, as each electrode assembly forming the electrode assembly stack 10, an electrode assembly 1b having an intermediate layer 15 between the negative electrode active material layer 12c of the negative electrode layer 12 and the negative electrode side solid electrolyte layer 13b.

### [Intermediate Layer 15]

The intermediate layer 15 can be made of, for example, particles composed of carbon and a metal element that forms an alloy with Li, such as SiC, SnC, AgC, or MgC, Li alloy foil, such as LiIn, LiAg, LiAl, or LiMg, a resin containing a liquid containing a Li-ion conductor, such as an ionic liquid, or the like.

In the present embodiment, if each electrode assembly forming the electrode assembly stack 10 is an electrode assembly 1b having an intermediate layer between the negative electrode layer 12 and the negative electrode side solid electrolyte layer 13b, Li metal deposition and dissolution become more uniform, and variations in performance of each electrode assembly 1b included in the electrode assembly stack 10 can be more effectively inhibited.

### [Method for Manufacturing Solid-State Battery]

In the present embodiment, the case of manufacturing a solid-state battery including the electrode assembly stack 10 shown in FIG. 1 will be described as an example of the method for manufacturing a solid-state battery.

The method for manufacturing a solid-state battery of the present embodiment involves the following (first process) to (fourth process).

### (First Process)

In the first process, the plurality of electrode assemblies 1 shown in FIG. 1 are formed.

First, a positive electrode composite containing a positive electrode active material is applied using a die coater to both sides of a current collector sheet that will become the positive electrode current collector 11a, and the positive electrode active material layer 11c is formed by a known method such as drying.

Next, a solid electrolyte material is transferred by a known method to both front and back surfaces of the positive electrode current collector 11a, which has the positive electrode active material layer 11c formed by the above-described method. After that, using a roll press, the positive electrode side solid electrolyte layer 13a integrated with the positive electrode active material layer 11c is formed, which is punched out to a specified shape.

Thus, on both the front and back surfaces of a single positive electrode current collector 11a, positive electrode pieces are formed, each having the positive electrode active material layer 11c, the positive electrode side solid electrolyte layer 13a, and the positive electrode current collector tab 11b integrally formed with the positive electrode current collector 11a.

In the present embodiment, a case in which the solid electrolyte material is transferred to both the front and back surfaces of the positive electrode current collector 11a, and then the current collector sheet is punched into a predetermined shape has been described as an example, but before transferring the solid electrolyte material to both the front and back surfaces of the positive electrode current collector 11a, the current collector sheet provided with the positive electrode active material layer 11c may be punched out, and then the solid electrolyte material may be transferred to both the front and back surfaces of the positive electrode current collector 11a.

Further, the negative electrode active material layer 12c is formed by a known method on one surface of a current collector sheet that will become the negative electrode current collector 12a, and this is then punched out or otherwise used to form the negative electrode layer 12, which has the negative electrode current collector tab 12b integrally formed with the negative electrode current collector 12a. After that, a solid electrolyte material is transferred by a known method onto the negative electrode layer 12 formed on one surface of the negative electrode current collector 12a. After that, using a roll press, the negative electrode side solid electrolyte layer 13b integrated with the negative electrode active material layer 12c is formed.

Thus, negative electrode pieces are formed, each having the negative electrode active material layer 12c provided on the one surface of the negative electrode current collector 12a, the negative electrode side solid electrolyte layer 13b formed thereon, and the positive electrode current collector tab 11b integrally formed with the negative electrode current collector 12a.

Next, the frame-shaped insulating member 14 is disposed on the negative electrode side solid electrolyte layer 13b side of the negative electrode piece formed in this manner, so that the negative electrode active material layer 12c is located inward from the outer surface of the insulating member 14 in a plan view. If the insulating member 14 is a separate member from the positive electrode active material layer 11c, the insulating member 14 can be formed, for example, by processing an insulating material into a predetermined shape and size, and then placing it so that it covers at least a portion of the periphery of the positive electrode layer 11.

A case in which the insulating member 14 is a separate member from the positive electrode active material layer 11c has been described above, but if the insulating member 14 is a member integrated with the positive electrode active material layer 11c, the insulating member 14 can be formed, for example, by the method described below. That is, the insulating member 14 can be formed by dissolving an insulating material in a solvent such as an organic solvent to form a slurry, which is then coated around the positive electrode layer 11 of the positive electrode piece and dried.

After that, among the two positive electrode layers 11 and positive electrode side solid electrolyte layers 13a included in the positive electrode piece, one of the positive electrode layers 11 and positive electrode side solid electrolyte layers 13a is housed inside the insulating member 14, and a periphery of the one positive electrode layer 11 is horizontally covered by the insulating member 14. In this case, the positive electrode current collector tab 11b included in the positive electrode piece and the negative electrode current collector tab 12b included in the negative electrode layer 12 are disposed to extend in opposite directions (left and right directions in FIG. 1) relative to the electrode assembly stack 10.

Next, the frame-shaped insulating member 14 is further disposed on the positive electrode side solid electrolyte layer 13a of the positive electrode piece that is not housed inward from the insulating member 14, and the positive electrode layer 11 and the positive electrode side solid electrolyte layer 13a are housed inward from the insulating member 14.

Next, the negative electrode piece is disposed with the negative electrode side solid electrolyte layer 13b facing the positive electrode side solid electrolyte layer 13a. In this case, the negative electrode piece is disposed so that the negative electrode active material layer 12c is positioned inward from the outer surface of the frame-shaped insulating member 14 in a plan view.

After that, uniaxial pressing is performed for 1 to 10 minutes at a pressure of 100 MPa to 120 MPa, for example.

Through these steps, the plurality of electrode assemblies 1 as shown in FIG. 1 are formed.

### (Second Process)

In the second process, the resistance values of the plurality of electrode assemblies 1 formed in the first process are measured. Then, by calculating a standard deviation of the obtained measurement results and dividing it by an average value of the measurement results, the coefficient of variation of the resistance values of plurality of electrode assemblies 1 is calculated. Here, the coefficient of variation indicates the standard deviation (σ) divided by the average value.

Then, the plurality of set resistance electrode assemblies 1a are selected from the plurality of electrode assemblies 1 so that the coefficient of variation of the resistance values of the plurality of electrode assemblies 1 falls within a predetermined range. Thus, variations in the resistance values of each of the set resistance electrode assemblies 1a forming the electrode assembly stack 10 is inhibited, making it easier to obtain a solid-state battery with a sufficient capacity.

In the second process, it is preferable to measure the AC resistance values (ACRs) as the resistance values of each of the electrode assemblies 1. In the case of measuring the AC resistance values as the resistance values of the electrode assemblies 1, the resistance values can be measured in a shorter time than a case of using the DC resistance values. For this reason, the coefficient of variation of the resistance values of each of the electrode assemblies 1 can be calculated in a shorter time, and variations in the resistance values of each of the set resistance electrode assemblies 1a forming the electrode assembly stack 10 can be efficiently inhibited.

As a method for measuring the AC resistance values, for example, a known method can be used, such as measuring the current amplitude response under conditions of a frequency of 1 kHz and a voltage amplitude of 10 mV.

In the present embodiment, in the case of using the AC resistance values (ACRs) as the resistance values of each of the electrode assemblies 1, it is preferable to select the plurality of set resistance electrode assemblies 1a from the plurality of electrode assemblies 1 so that the coefficient of variation in the resistance values is 15% or less, and it is more preferable to select the plurality of set resistance electrode assemblies 1a from the plurality of electrode assemblies 1 so that the coefficient of variation in the resistance values is 10% or less. Thus, variations in the resistance values of each of the set resistance electrode assemblies 1a forming the electrode assembly stack 10 are more effectively inhibited, making it easier to obtain a solid-state battery with a large capacity.

Further, the present inventors have considered that, in order to improve the yield of the electrode assembly stack 10 at the end of chemical formation in the fourth process described below, it is preferable to evaluate characteristics of the set resistance electrode assemblies 1a used as a material for the electrode assembly stack 10 and reduce the number of electrode assembly stacks 10 that do not achieve the specified performance at the end of chemical formation.

Then, the present inventors have conducted extensive research, focusing on a relationship between the characteristics of the set resistance electrode assemblies 1a used as the material for the electrode assembly stack 10 and the characteristics of the electrode assembly stack 10 after the chemical formation.

As a result, the present inventors have found that there is a correlation between the AC resistances (ACRs) of the electrode assemblies 1 used as the material for the electrode assembly stack 10 and the DC resistance value (DCR) of the electrode assembly stack 10 when discharged for 10 seconds after chemical formation.

In the present specification, the expression “DC resistance value of the electrode assembly stack when discharged for 10 seconds after chemical formation” indicates a value calculated by measuring a DC resistance value (DCR) of the electrode assembly stack 10 under the measurement conditions shown below after performing chemical formation under the conditions shown below.

### (Conditions for Chemical Formation of Electrode Assembly Stack 10)

As a chemical formation treatment for the electrode assembly stack 10, charging and discharging were performed at a temperature of 60° C., a restraining load of 3 MPa, a C-rate of 0.1 C, and in the range of 2.65 V to 4.3 V.

(Conditions for measuring the DC resistance value (DCR) of the electrode assembly stack 10)

The electrode assembly stack 10 after the chemical formation was adjusted to a state of charge (SOC) of 50%, and a voltage drop was measured when the electrode assembly stack 10 was discharged from the state of charge (SOC) of 50% at 0.7 C for 10 seconds, thereby performing calculations using these results.

On the basis of the above correlation, the present inventors have investigated a method for manufacturing, with a high yield, the electrode assembly stack 10 whose DC resistance value (DCR) when discharged for 10 seconds after the chemical formation is within the range of a set DC resistance value, which is a preset target value.

As a result, the present inventors have found that, in the second process, it is sufficient to select a plurality of set resistance electrode assemblies 1a each having an AC resistance value (ACR) within a predetermined range from the plurality of electrode assemblies 1 that are the material for the electrode assembly stack 10, so that the AC resistance falls within the predetermined range calculated on the basis of the set DC resistance value (DCR) of the electrode assembly stack 10 when discharged for 10 seconds after chemical formation.

Accordingly, in the present embodiment, it is preferable to select the plurality of set resistance electrode assemblies 1a from the plurality of electrode assemblies 1 in the second process, so that the AC resistances of the plurality of electrode assemblies 1 fall within the predetermined range calculated on the basis of the set DC resistance value (DCR) of the electrode assembly stack 10 when discharged for 10 seconds after the chemical formation. Thus, the electrode assembly stack 10 whose DC resistance value (DCR) when discharged for 10 seconds after the chemical formation falls within the set DC resistance range is more likely to be formed, and the electrode assembly stack 10 can be manufactured with a high yield.

Further, the present inventors have found that, in the second process, by selecting the plurality of set resistance electrode assemblies 1a from the plurality of electrode assemblies 1 so that the set DC resistance value when the electrode assembly stack 10 is chemically formed and discharged for 10 seconds can be approximated by a function of the AC resistance values of the electrode assemblies 1, it becomes even easier to form the electrode assembly stack 10 whose DC resistance value (DCR) when discharged for 10 seconds after the chemical formation is within the range of the set DC resistance value.

As the function of the AC resistance values of the electrode assemblies 1 that can approximate the set DC resistance value when the electrode assembly stack 10 is chemically formed and discharged for 10 seconds, there is, for example, a regression line shown in the following equation (1), which is a function showing a relationship between the AC resistance values (ACRs) (Ωcm²) of the electrode assemblies used as the material for the electrode assembly stack 10 and the set DC resistance value (DCR) (Ωcm²) at a temperature of 60° C. when the electrode assembly stack 10 is chemically formed and discharged for 10 seconds.

$$y = ax + b \qquad ( 1 )$$

(In the equation (1), x is an AC resistance value (ACR) (Ωcm²) of an electrode assembly used as a material for the electrode assembly stack 10. y is a set DC resistance value (DCR) (Ωcm²) at a temperature of 60° C. when the electrode assembly stack 10 is discharged for 10 seconds after the chemical formation. a and b are greater than 0.)

In the equation (1), x is the AC resistance value (ACR) of the set resistance electrode assembly 1a selected from the plurality of electrode assemblies 1 as the material for the electrode assembly stack 10, which is preferably 20 Ωcm² to 160 Ωcm², and more preferably 40 Ωcm² to 160 Ωcm². If the AC resistance value of the set resistance electrode assembly 1a is 20 Ωcm² or more, the electrode assemblies 1 with less variation in the resistance value are more likely to be obtained, which is thus preferable from the perspective of productivity. If the AC resistance value of the set resistance electrode assembly 1a is 160 Ωcm² or less, the electrode assembly stack 10 with a low resistance value can be manufactured, which is thus preferable.

The range of the coefficient of variation of the AC resistance values (ACRs) of the set resistance electrode assemblies 1a selected from the plurality of electrode assemblies 1, represented by x in the equation (1), is preferably 15% or less, more preferably 10% or less, and the smaller the range of the coefficient of variation, the better. If the range of the coefficient of variation of the AC resistance values of the set resistance electrode assemblies 1a is 15% or less, the electrode assembly stack 10 with less variation in the resistance values of the set resistance electrode assemblies 1a is likely to be obtained.

In the equation (1), y is the set DC resistance value (Ωcm²) at a temperature of 60° C. when the electrode assembly stack 10 is discharged for 10 seconds after the chemical formation, and may be, for example, 20 Ωcm² or less, 17 Ωcm² or less, or 15 Ωcm² or less. If y in the equation (1) is 20 Ωcm² or less, the electrode assembly stack (10) with excellent characteristics is more likely to be obtained, in which the plurality of set resistance electrode assemblies 1a are selected from the plurality of electrode assemblies 1 so that the range is within the range satisfying the equation (1), and thus the DC resistance value (DCR) when discharged for 10 seconds after the chemical formation is 20 Ωcm² or less.

In the equation (1), a is preferably in the range of 1 or more and 20 or less, and more preferably in the range of 2 or more and 10 or less.

In the equation (1), b is preferably in the range of 0 or more and 10 or less, and more preferably in the range of 1 or more and 5 or less.

In the equation (1), the coefficient of determination R² is preferably in the range of 0.5 or more and 1.0 or less. From the perspective of productivity, the coefficient of determination R² may be in the range of 0.5 or more and 0.9 or less. When the coefficient of determination R² in the equation (1) is 0.5 or more, the relationship between x and y in the equation (1) has a strong correlation with the regression line of the equation (1). For this reason, it becomes even easier to form the electrode assembly stack 10 whose DC resistance value (DCR) when discharged for 10 seconds after the chemical formation is within the set DC resistance value range. As a result, the electrode assembly stack 10 can be manufactured with a higher yield.

In the second process, it is preferable to select the plurality of set resistance electrode assemblies 1a from the plurality of electrode assemblies 1 so that the AC resistance values of the plurality of electrode assemblies 1 fall within the predetermined range calculated on the basis of the set DC resistance value of the electrode assembly stack 10 when discharged for 10 seconds after the chemical formation.

Specifically, for example, it is preferable to select from the plurality of electrode assemblies 1 those with the AC resistance values in the range of 20 Ωcm² to 160 Ωcm² so that the set DC resistance value (DCR) of the electrode assembly stack 10 when discharged for 10 seconds after the chemical formation is within the range of 5 Ωcm² to 40 Ωcm².

Further, in the second process, it is preferable to select the plurality of set resistance electrode assemblies 1a from the plurality of electrode assemblies 1 so that the set DC resistance value when the electrode assembly stack 10 is chemically formed and discharged for 10 seconds can be approximated by the function of the AC resistances of the electrode assemblies 1.

Specifically, it is preferable to select the plurality of electrode assemblies 1 with the AC resistance values in the range of 20 Ωcm² to 160 Ωcm² from the plurality of electrode assemblies 1, for example, so that the set DC resistance value (DCR) of the electrode assembly stack 10 when discharged for 10 seconds is within the range of 5 Ωcm² to 40 Ωcm², and from among these, it is preferable to select the plurality of set resistance electrode assemblies 1a from the plurality of electrode assemblies 1 so that a correlation function between the AC resistance value (ACR) of the electrode assembly used as the material for the electrode assembly stack 10 and the set DC resistance value (DCR) at a temperature of 60° C. when the electrode assembly stack 10 is chemically formed and then discharged for 10 seconds is 0.5 or greater.

The relationship between the AC resistance value (ACR) of the electrode assembly used as the material for the electrode assembly stack 10 and the DC resistance value of the electrode assembly stack 10 when discharged for 10 seconds after the chemical formation is not limited to the linear approximation shown in the equation (1) and may be a polynomial approximation.

In the second process, it is preferable to select the plurality of set resistance electrode assemblies 1a from the plurality of electrode assemblies 1 so that a coefficient of variation in capacity of the plurality of set resistance electrode assemblies 1a is within a predetermined range. Thus, the electrode assembly stack 10 with less variation in capacity of the plurality of set resistance electrode assemblies 1a is obtained. In the present embodiment, it is preferable to select the plurality of set resistance electrode assemblies 1a from the plurality of electrode assemblies 1 so that the coefficient of variation in capacity is 5% or less, and it is more preferable to select the plurality of set resistance electrode assemblies 1a from the plurality of electrode assemblies 1 so that the coefficient of variation in capacity is 3% or less. By selecting the plurality of set resistance electrode assemblies 1a from the plurality of electrode assemblies 1 so that the coefficient of variation in capacity is 5% or less, the electrode assembly stack 10 with less variation in capacity of the plurality of set resistance electrode assemblies 1a is obtained.

In the present embodiment, in the second process, the method shown below may be used as the method for selecting the plurality of set resistance electrode assemblies 1a from the plurality of electrode assemblies 1 so that the coefficient of variation in capacity of the plurality of set resistance electrode assemblies 1a falls within the predetermined range.

That is, the basis weight of the positive electrode active material in the positive electrode active material layer 11c of the positive electrode layer 11 in the electrode assemblies 1 correlates with the capacity of the electrode assemblies 1. For this reason, by selecting the plurality of set resistance electrode assemblies 1a from the plurality of electrode assemblies 1 so that the coefficient of variation in basis weight of the positive electrode active material layer of the plurality of set resistance electrode assemblies 1a falls within the predetermined range, it is possible to select the plurality of set resistance electrode assemblies 1a whose coefficient of variation in the capacity of the plurality of set resistance electrode assemblies 1a falls within the predetermined range.

Specifically, in the first process, the positive electrode active material layer 11c of the positive electrode layer 11 is formed, the basis weight of the positive electrode active material in the positive electrode active material layer 11c is measured, and then, before laminating the positive electrode layer 11 and other members that will become the electrode assembly 1, only those positive electrode layers 11 whose coefficient of variation in the basis weight of the positive electrode active material layer is within the predetermined range is selected from the manufactured positive electrode layers 11. After that, using only the positive electrode layers 11 whose coefficient of variation in the basis weight of the positive electrode active material layer is within the predetermined range, the solid electrolyte layer 13, the negative electrode layer 12, the insulating member 14, and the like, which form the electrode assembly 1, are laminated, and thus the plurality of electrode assemblies 1 are formed.

Thus, in the second process, the set resistance electrode assemblies 1a selected from the plurality of electrode assemblies 1 all have the coefficient of variation in the basis weight of the positive electrode active material layer within the predetermined range, and as a result, the coefficient of variation in the capacity of the plurality of set resistance electrode assemblies 1a may be set to be within the predetermined range.

By using this method, for example, it is possible to reduce the effort required to form the electrode assemblies 1 that cannot be used as the material for the electrode assembly stack 10, or to reduce amounts of the solid electrolyte layer 13 and the negative electrode layer 12 used to manufacture the electrode assemblies 1 that will not be used as the material for the electrode assembly stack 10.

### (Third Process)

In the third process, the set resistance electrode assemblies 1a are stacked.

Next, the plurality of stacked set resistance electrode assemblies 1a are connected in parallel to each other to form the electrode assembly stack 10. Then, in the set resistance electrode assemblies 1a forming the electrode assembly stack 10, the positive electrode current collector tabs 11b of the positive electrode layers 11 are electrically connected to each other, and the negative electrode current collector tabs 12b of the negative electrode layers 12 are electrically connected to each other.

After that, the electrode assembly stack 10, in which the plurality of set resistance electrode assemblies 1a are connected in parallel to each other, is restrained using a known restraining jig (not shown) such as an end plate, and pressure is applied in the stacking direction of the electrode assembly stack 10. The pressure (restraining load) applied in the stacking direction of the electrode assembly stack 10 can be, for example, in the range of 0.5 MPa to 5 MPa, and preferably in the range of 1 MPa to 3 MPa. After that, the electrode assembly stack 10 restrained by the restraining jig is housed in a case (not shown).

### (Fourth Process)

In the fourth process, the electrode assembly stack 10 is chemically formed.

As the method for chemically forming the electrode assembly stack 10, for example, a method of performing charging and discharging at a temperature of 60° C., a restraining load of 3 MPa, a C-rate of 0.1 C, and in the range of 2.65 V to 4.3 V, or the like can be exemplified.

In the fourth process, by chemically forming the electrode assembly stack 10 to produce the electrode assembly stack 10, the electrode assembly stack 10 in which a coefficient of variation in DC resistance values (DCRs) of the plurality of set resistance electrode assemblies 1a forming the electrode assembly stack 10 is 10% or less is preferably manufactured. In the present embodiment, in the second process, the plurality of set resistance electrode assemblies 1a are selected from the plurality of electrode assemblies 1 so that the coefficient of variation in the resistance values of the plurality of electrode assemblies 1 is within the predetermined range, and thus the plurality of set resistance electrode assemblies 1a forming the electrode assembly stack 10 have less variation in the resistance values. For this reason, in the fourth process, the electrode assembly stack 10 in which the coefficient of variation in the DC resistance values (DCRs) of the plurality of set resistance electrode assemblies 1a is 10% or less is likely to be obtained.

Specifically, in a case in which, in the second process, the resistance values of the plurality of electrode assemblies 1 are AC resistance values, and the plurality of set resistance electrode assemblies 1a are selected from the plurality of electrode assemblies 1 so that the coefficient of variation in the resistance values falls within the range of 10% or less, the coefficient of variation in the DC resistance values (DCRs) of the plurality of set resistance electrode assemblies 1a forming the electrode assembly stack 10 is 10% or less. Such a solid-state battery is preferable because it has excellent characteristics. The coefficient of variation in the DC resistance values (DCRs) of the plurality of electrode assemblies 1 forming the electrode assembly stack 10 after the chemical formation is preferably 9.9% or less, and more preferably 9.8% or less.

Further, in the fourth process, by chemically forming the electrode assembly stack 10, the electrode assembly stack 10 having a DC resistance value (DCR) of 20 Ωcm² or less at a temperature of 60° C. is preferably manufactured. Such a solid-state battery is preferable because it has excellent characteristics. The DC resistance value (DCR) of the electrode assembly stack 10 is preferably 17 Ωcm² or less at a temperature of 60° C., and more preferably 15 Ωcm² or less.

Further, in the fourth process, by chemically forming the electrode assembly stack 10, the electrode assembly stack 10 having a DC resistance value (DCR) of 70 Ωcm² or less at a temperature of 25° C. is also preferably manufactured.

By performing the above steps, the solid-state battery of the present embodiment is obtained.

Although the embodiments of the present invention have been described above. the above-mentioned embodiments of the present invention are intended to facilitate understanding of the present invention and do not limit the present invention. The present invention may be modified and improved without departing from the spirit and scope of the claims, and naturally, equivalents thereof are included within the scope of the present invention.

### EXAMPLES

### Experimental Examples

Eleven electrode assemblies 1 of each of seven types satisfying the conditions listed below were manufactured, and the AC resistance values (ACRs) of each of the electrode assembly 1 were measured. From the electrode assemblies 1 whose AC resistance values were measured, those with AC resistance values in the range of 0.05Ω to 2.5Ω at 1 kHz were selected, one to five electrode assemblies 1 were connected in parallel, thereby manufacturing ten electrode assembly stack 10 samples simulating the stacked electrode assemblies 1.

The ten electrode assembly stack 10 samples thus obtained were each chemically formed under the conditions listed below, and the DC resistance value (DCR) of each was measured under the conditions listed below.

### (Conditions of Electrode Assemblies Used as Materials for Electrode Assembly Stack 10 Sample)

For the electrode assemblies, the electrode assembly 1 shown in FIG. 1, which has the positive electrode layer 11, the solid electrolyte layer 13, the negative electrode layer 12, and the insulating member 14, and the electrode assembly 1b shown in FIG. 2, which has the positive electrode layer 11, the solid electrolyte layer 13, the negative electrode layer 12, the insulating member 14, and the intermediate layer 15, were used.

For the positive electrode layer 11, a layer that includes the positive electrode current collector 11a made of aluminum (Al) foil and the positive electrode active material layer 11c containing an argyrodite-type sulfide solid electrolyte as the positive electrode active material was used. The content of the positive electrode active material contained in the positive electrode active material layer 11c was set to be within the range of 60% to 80% by mass. In addition, the basis weight of the positive electrode active material layer 11c was set to be within the range of 10 mg/cm² to 40 mg/cm².

For the negative electrode layer 12, a layer that includes the negative electrode current collector 12a made of copper (Cu) foil and the negative electrode active material layer 12c made of lithium metal foil was used. For the lithium metal foil, metal foil with a thickness in the range of 5 μm to 30 μm was used.

For the positive electrode side solid electrolyte layer 13a, a layer that has a solid electrolyte material content in the range of 98% to 99% by mass and a thickness in the range of 1 μm to 30 μm was used.

For the negative electrode side solid electrolyte layer 13b, a layer that has a solid electrolyte material content in the range of 95% to 99% by mass and a thickness in the range of 30 μm to 120 μm was used.

In the electrode assembly 1 shown in FIG. 1, for the insulating member 14, a member made of Nomex (registered trademark) was used.

In the electrode assembly 1b shown in FIG. 2, for the insulating member 14, a member made of alumina was used. For the intermediate layer 15 in the electrode assembly 1b shown in FIG. 2, a layer made of SiC was used.

### (Conditions for Chemical Formation of Electrode Assembly Stack 10 Samples)

For the chemical formation treatment for the electrode assembly stack 10 samples, charging and discharging were performed at a temperature of 60° C., a restraining load of 3 MPa, a C-rate of 0.1 C, and a voltage range of 2.65 V-4.3 V.

### (Conditions for Measuring DC Resistance Value (DCR) of Electrode Assembly Stack 10 Samples)

The electrode assembly stack 10 samples after the chemical formation were adjusted to a state of charge (SOC) of 50%, and the voltage drop was measured when the samples were discharged from the 50% state of charge (SOC) at 0.7 C for 10 seconds, thereby performing calculations using these results.

Next, using the results of the DC resistance values (DCRs) of the electrode assembly stack 10 samples after the chemical formation measured in this way, a scatter plot was created showing the relationship between the AC resistance value (ACR) of the electrode assembly used as the material for the electrode assembly stack 10 sample and the DC resistance value (DCR) of the electrode assembly stack 10 sample after chemically formed and discharged for 10 seconds.

As a result, it has been found that the AC resistance (ACR) (“X” in the equation (1A) below) of the electrode assembly 1 used as the material for the electrode assembly stack 10 sample, and the DC resistance (DCR) (“Y” in the equation (1A) below) of the electrode assembly stack 10 sample measured under the above conditions after the chemical formation have a positive correlation, as indicated by the regression line given by the following equation (1A):

$$Y = 8.83 X + 4.86 \qquad ( 1 A )$$

### Example 1

A solid-state battery of Example 1 including the electrode assembly stack 10 formed by stacking 12 layers of the set resistance electrode assemblies 1a shown in FIG. 1 was manufactured using the method described below.

### (First Process)

In the first process, 40 electrode assemblies 1 were formed.

Each of the electrode assemblies 1 was formed using the method described below. First, a current collector sheet made of aluminum (Al) foil with a thickness of 12 μm was prepared to serve as the positive electrode current collector 11a. A positive electrode composite having the composition shown below was applied to both sides of the current collector sheet using a die coater, followed by drying to form a 100 μm-thick positive electrode active material layer 11c.

The basis weight of the positive electrode active material included in each of the positive electrode active material layers 11c of the two positive electrode layers 11 forming one electrode assembly 1 was set with a targeted total basis weight of 54.8 mg/cm², and after the positive electrode active material layers 11c were actually formed on both sides of the current collector sheet, the basis weights of each were measured.

### “Composition of Positive Electrode Composite”

Positive electrode active material: NCM622; 60% by mass
Conductive aid: Li100 (trade name; manufactured by Denka) 35.8% by mass
Solid electrolyte: Argyrodite-type sulfide solid electrolyte (D50: 0.7 μm) 2.7% by mass
Binder: Fluorine-based rubber binder 1.3% by mass

Next, using the results of measuring the basis weight of the positive electrode active material of the positive electrode current collector 11a having the positive electrode active material layer 11c formed by the above method, a plurality of positive electrode current collectors 11a each having a specific positive electrode active material layer 11c were selected so that a coefficient of variation in the total positive electrode active material layer basis weight of the positive electrode active material of the positive electrode active material layer 11c included in each of the two positive electrode layers 11 was 0.8% or less.

Then, a solid electrolyte material containing 1.3 mass % of a solid electrolyte: argyrodite-type sulfide solid electrolyte (D50: 0.7 μm) and a binder: fluorine-based rubber binder was transferred onto both the front and back surfaces of the positive electrode current collector 11a that has the plurality of positive electrode active material layers 11c each having the coefficient of variation in the positive electrode active material layer basis weight in the range of 0.8% or less, and then roll-pressed to form 3 μm-thick positive electrode side solid electrolyte layers 13a integrated respectively with the positive electrode active material layers 11c.

After that, by punching it out into a predetermined shape, positive electrode pieces each having the positive electrode active material layer 11c, the positive electrode side solid electrolyte layer 13a, and the positive electrode current collector tab 11b integrally molded with the positive electrode current collector 11a were formed on both the front and back surfaces of a single positive electrode current collector 11a.

Further, a current collector sheet made of copper (Cu) foil with a thickness of 10 μm was also prepared to serve as the negative electrode current collector 12a. The negative electrode active material layer 12c made of lithium metal with a thickness of 20 μm was formed on one surface of the current collector sheet, and by punching it out, the negative electrode layer 12 having the negative electrode current collector tab 12b integrally molded with the negative electrode current collector 12a was formed.

After that, a solid electrolyte material containing 97.3 mass % of a solid electrolyte: argyrodite-type sulfide solid electrolyte (D50: 0.7 μm) and a binder: fluorine-based rubber binder was transferred onto the negative electrode layer 12 formed on one surface of the negative electrode current collector 12a, and roll-pressed to form a 100 μm-thick negative electrode side solid electrolyte layer 13b integrated with the negative electrode active material layer 12c.

Thus, the negative electrode piece including the negative electrode active material layer 12c disposed on one surface of the negative electrode current collector 12a, the negative electrode side solid electrolyte layer 13b formed thereon, and the positive electrode current collector tab 11b integrally molded with the negative electrode current collector 12a was formed.

Next, the insulating member 14 was placed on the negative electrode side solid electrolyte layer 13b side of the negative electrode piece formed in this way. As the insulating member 14, a frame-shaped made of Nomex (registered trademark) with a horizontal width of 11 mm and a thickness of 1.3 mm was prepared. The insulating member 14 was placed so that the negative electrode active material layer 12c was disposed inward from the outer surface of the insulating member 14 in a plan view.

After that, one of the two positive electrode layers 11 and positive electrode side solid electrolyte layers 13a included in the positive electrode pieces was housed inside the insulating member 14, and a periphery of one positive electrode layer 11 was horizontally covered with the insulating member 14. In this case, the positive electrode current collector tab 11b included in the positive electrode piece and the negative electrode current collector tab 12b included in the negative electrode layer 12 were disposed to extend in opposite directions (left and right directions in FIG. 1) relative to the electrode assembly stack 10.

Next, a frame-shaped insulating member 14 was further disposed on the positive electrode side solid electrolyte layer 13a of the positive electrode piece that was not housed inside the insulating member 14, and the positive electrode layer 11 and the positive electrode side solid electrolyte layer 13a were housed inside the insulating member 14.

Next, the negative electrode piece was disposed with the negative electrode side solid electrolyte layer 13b side facing the positive electrode side solid electrolyte layer 13a. In this case, it was disposed so that a position of the negative electrode active material layer 12c was located inward from the outer surface of the frame-shaped insulating member 14 in a plan view.

After that, uniaxial pressing was performed at a pressure of 120 MPa for 1 minute.

Through the above steps, 40 electrode assemblies 1 were formed.

### (Second Process)

In the second process, the AC resistance value (ACR) of each of the 40 electrode assemblies 1 formed in the first process was measured. The AC resistance value was measured using a method of measuring current amplitude response under conditions of a frequency of 1 kHz and a voltage amplitude of 10 mV.

Then, a standard deviation of the obtained AC resistance value (ACR) measurement results was calculated and divided by the average of the measurement results to calculate the coefficient of variation for the AC resistance values (ACRs) of the plurality of electrode assemblies 1.

Next, from the plurality of electrode assemblies 1, 40 set resistance electrode assemblies 1a with a coefficient of variation in resistance value of 7% or less were selected.

Further, set resistance electrode assemblies 1a were selected from the 40 set resistance electrode assemblies 1a selected under the conditions shown below, so that a relationship between the AC resistance values (ACR) of the electrode assembly 1 used as the material for the electrode assembly stack 10 and the set DC resistance value (DCR) of the electrode assembly stack 10 chemically formed and discharged for 10 seconds could be linearly approximated by the equation (1A) obtained in the above experimental example, and 27 set resistance electrode assemblies were selected.

### (Conditions)

The set DC resistance value (DCR) represented by “Y” in the equation (1A) was set to 17 (Ωcm²). Among the plurality of electrode assemblies 1 manufactured, those with AC resistance values in the range of 0.5Ω to 2.5Ω relative to the value of “X” calculated by the equation (1A) were selected.

In the 27 set resistance electrode assemblies 1a selected in the second process, the coefficient of variation in the positive electrode active material layer basis weight was 0.8% or less. The coefficient of variation in the AC resistance values (ACRs) of the 27 set resistance electrode assemblies 1a was 7.0% or less.

### (Third Process)

In the third process, the 27 set resistance electrode assemblies 1a selected in the second process were stacked. Next, the stacked set resistance electrode assemblies 1a were connected in parallel to each other to form the electrode assembly stack 10.

Then, the positive electrode current collector tabs 11b of the positive electrode layers 11 of the set resistance electrode assemblies 1a forming the electrode assembly stack 10 were electrically connected to each other, and the negative electrode current collector tabs 12b of the negative electrode layers 12 were electrically connected to each other.

After that, the electrode assembly stack 10 was restrained using end plates, and a pressure of 3 MPa was applied in the stacking direction of the electrode assembly stack 10.

After that, the electrode assembly stack 10 restrained by the restraining jig was housed in a case (not shown).

### (Fourth Process)

In the fourth process, the electrode assembly stack 10 was chemically formed using the method described below.

The electrode assembly stack 10 was chemically formed under conditions of a temperature of 60° C., a restraining load of 3 MPa, and an applied current of 0.1 C.

By performing the above steps, the solid-state battery of Example 1 was obtained, in which 27 set resistance electrode assemblies 1a were connected in parallel to each other.

### Example 2

A solid-state battery of Example 2, in which 12 set resistance electrode assemblies 1a were connected in parallel to each other, was obtained in the same manner as Example 1, except that 12 set resistance electrode assemblies 1a were selected in the third process.

In the 12 set resistance electrode assemblies 1a selected in the second process of Example 2, the coefficient of variation in the positive electrode active material layer basis weight was 0.8% or less. In the 12 set resistance electrode assemblies 1a, the coefficient of variation in the AC resistance values (ACR) was 7.0% or less.

### Reference Example 1

A single-cell solid-state battery of Reference Example 1 was obtained in the same manner as in Example 1, except that only one electrode assembly 1 manufactured in the same manner as in Example 1 was used.

Next, a specific capacity and a resistance value per positive electrode active material were measured for each of the solid-state batteries of Examples 1 and 2, and Reference Example 1 obtained in this manner, using the methods described below. The results are shown in Table 1.

### [Method for Measuring Specific Capacity Per Positive Electrode Active Material]

The discharge capacity was measured in the voltage range of 2.65 V to 4.3 V under conditions of a temperature of 60° C., a restraining load of 3 MPa, and an applied current of 0.1 C. The specific capacity was calculated by dividing the measured discharge capacity obtained in this manner by a mass of the positive electrode active material used in the solid-state battery.

### [Method for Measuring Resistance Value]

Current was applied for 10 seconds at 0.1 C increments at a temperature of 60° C., a restraining load of 3 MPa, a state of charge (SOC) of 50%, and a C-rate range of 0.1 C to 0.7 C, and the cell voltage was measured. The resistance value at each C-rate was calculated by dividing the absolute value of an amount of cell voltage drop before and after the current application by the current value, and a value obtained by averaging the resistance values at each C-rate was used as the resistance value. Also, the current value was calculated by multiplying an electrode assembly design capacity by the C-rate. For example, if the electrode assembly design capacity is 150 mAh, the current value at 0.1 C is 15 mA.

TABLE 1

| | Specific | |
|---|---|---|
| | capacity | |
| | per positive | |
| | electrode | 10 second |
| | active | discharge |
| | material | DCR |
| | (mAh/g) | (Ωcm²) |
| Reference | 177.7 | 15.6 |
| Example 1 | | |
| Example 1 | 177.2 | 16.5 |
| Example 2 | 179.3 | 13.6 |

As shown in Table 1, the solid-state battery of Example 1, in which 27 layers of set resistance electrode assemblies 1a were stacked, and the solid-state battery of Example 2, in which 12 layers of set resistance electrode assemblies 1a were stacked, had specific capacities and resistance values per positive electrode active material that are equivalent to those of the single-cell solid-state battery of Reference Example 1. Thus, it has been confirmed that, in Examples 1 and 2, the variation in the resistance value of each of the set resistance electrode assemblies 1a forming the electrode assembly stack 10 is inhibited.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 Electrode assembly
1a Set resistance electrode assembly
10 Electrode assembly stack
11 Positive electrode layer
11a Positive electrode current collector
11b Positive electrode current collector tab
11c Positive electrode active material layer
12 Negative electrode layer
12a Negative electrode current collector
12b Negative electrode current collector tab
12c Negative electrode active material layer
13 Solid electrolyte layer
13a Positive electrode side solid electrolyte layer
13b Negative electrode side solid electrolyte layer
14 Insulating member

What is claimed is:

1. A method for manufacturing a solid-state battery comprising:
a first process of forming a plurality of electrode assemblies each including a positive electrode layer, a solid electrolyte layer, and a negative electrode layer;
a second process of selecting a plurality of set resistance electrode assemblies from the plurality of electrode assemblies so that a coefficient of variation in resistance values of the plurality of electrode assemblies falls within a predetermined range;
a third process of stacking the set resistance electrode assemblies to form an electrode assembly stack; and
a fourth process of chemically forming the electrode assembly stack.

2. The method for manufacturing a solid-state battery according to claim 1, wherein the resistance values are AC resistance values.

3. The method for manufacturing a solid-state battery according to claim 1, wherein, in the second process, the plurality of set resistance electrode assemblies are selected from the plurality of electrode assemblies so that AC resistance values of the plurality of electrode assemblies fall within a predetermined range calculated on the basis of a set DC resistance value of the electrode assembly stack when discharged for 10 seconds after the chemical formation is performed in the fourth process.

4. The method for manufacturing a solid-state battery according to claim 1, wherein, in the second process, the plurality of set resistance electrode assemblies are selected from the plurality of electrode assemblies so that a set DC resistance value of the electrode assembly stack when chemically formed and discharged for 10 seconds is able to be approximated by a function of AC resistance values of the electrode assemblies.

5. The method for manufacturing a solid-state battery according to claim 1, wherein, in the second process, the plurality of set resistance electrode assemblies are selected from the plurality of electrode assemblies so that a relationship between the set DC resistance value of the electrode assembly stack when chemically formed and discharged for 10 seconds and the AC resistance values of the electrode assemblies is able to be linearly approximated.

6. The method for manufacturing a solid-state battery according to claim 1, wherein the resistance values are AC resistance values, and the coefficient of variation in the resistance values is 15% or less.

7. The method for manufacturing a solid-state battery according to claim 1, wherein the resistance values are AC resistance values, and the coefficient of variation in the resistance values is 10% or less.

8. The method for manufacturing a solid-state battery according to claim 1, wherein, by chemically forming the electrode assembly stack in the fourth process, the electrode assembly stack in which a coefficient of variation in DC resistance values of the plurality of set resistance electrode assemblies forming the electrode assembly stack is 10% or less is manufactured.

9. The method for manufacturing a solid-state battery according to claim 1, wherein, by chemically forming the electrode assembly stack in the fourth process, the electrode assembly stack having a DC resistance value of 20 Ωcm² or less at a temperature of 60° C. is manufactured.

10. The method for manufacturing a solid-state battery according to claim 1, wherein, in the second process, the plurality of set resistance electrode assemblies are selected from the plurality of electrode assemblies so that a coefficient of variation in capacities of the plurality of set resistance electrode assemblies falls within a predetermined range.

11. The method for manufacturing a solid-state battery according to claim 10, wherein the coefficient of variation in the capacities is 5% or less.

12. The method for manufacturing a solid-state battery according to claim 10, wherein the coefficient of variation in the capacities is 3% or less.

13. The method for manufacturing a solid-state battery according to claim 1, wherein the negative electrode layer contains lithium metal or a lithium alloy.

14. A solid-state battery manufactured by the method for manufacturing a solid-state battery according to claim 1.

15. A solid-state battery comprising an electrode assembly stack formed by stacking a plurality of electrode assemblies, each having a positive electrode layer, a solid electrolyte layer, and a negative electrode layer,
wherein a specific capacity per positive electrode active material of the electrode assembly stack is 150 mAh/g or more, and
a DC resistance value of the electrode assembly stack at 60° C. when discharged for 10 seconds is 18 Ωcm² or less.

16. The solid-state battery according to claim 15,
wherein the specific capacity per positive electrode active material of the electrode assembly stack is 150 mAh/g or more, and
the DC resistance value of the electrode assembly stack at 60° C. when discharged for 10 seconds is 2 Ωcm² or more and 17 Ωcm² or less.
